(19) United States
(12) Patent Application Publication
(10) Pub. No.: US 2009/0078961 A1
(43) Pub. Date: Mar. 26, 2009

(54) NITRIDE-BASED LIGHT EMITTING DEVICE

(75) Inventor: Jae Bin CHOI, Ansan-si (KR)

Correspondence Address: H.C. PARK & ASSOCIATES, PLC, 8500 LEESBURG PIKE, SUITE 7500, VIENNA, VA, 22182, US

(73) Assignee: SEOUL OPTO DEVICE CO., LTD., Ansan-si (KR)

(21) Appl. No.: 12/173,319

(22) Filed: Jul. 15, 2008

(30) Foreign Application Priority Data
Sep. 20, 2007 (KR) 10-2007-0096081

(51) Int. Cl. H01L 33/00

(52) U.S. Cl. 257/103; 257/E33.005

(57) ABSTRACT

The present invention relates to a nitride-based light emitting device having a buffer layer, an n-type nitride semiconductor layer, an active layer and a p-type semiconductor layer sequentially formed on a substrate, wherein an Al₁₋ₓSiₓN interlayer is formed inside of the n-type nitride semiconductor layer. Accordingly, threading dislocation generated from the initial stage of the growth of the n-type nitride-based semiconductor layer can be reduced, and tensile strain can be decreased, thereby implanting a nitride-based light emitting device with high reliability.

### CROSS REFERENCE TO RELATED APPLICATIONS

This application claims priority from and the benefit of Korean Patent Application No. 10-2007-0096081, filed on Sep. 20, 2007, which is hereby incorporated by reference for all purposes as if fully set forth herein.

### BACKGROUND OF THE INVENTION

1. Field of the Invention

The present invention relates to a nitride-based light emitting device, and more particularly, to a high quality nitride-based light emitting device, wherein an interlayer is formed inside of an n-type nitride-based semiconductor layer, so that threading dislocation generated from the initial stage of the growth of the n-type nitride-based semiconductor layer due to lattice mismatch between the substrate and the n-type nitride-based semiconductor layer is reduced, and tensile strain generated while the n-type nitride-based semiconductor layer is grown is decreased, thereby improving electrostatic voltage resistance.

2. Description of the Related Art

In general, nitride-based semiconductors are widely used for blue/green light emitting diodes or laser diodes as light sources of full-color displays, traffic lights, general illuminators and optical communication devices. Such a nitride-based light emitting device has an InGaN-based active layer of an InGaN-based multiple quantum well structure, which is interposed between n-type and p-type nitride semiconductor layers, and emits light through recombination of electrons and holes in the active layer.

A lattice mismatch of about 14% exists between a sapphire (Al₂O₃) substrate and GaN.

A variety of buffer layers are used to reduce the lattice mismatch, but a threading dislocation density of 10⁸ to 10¹⁰ cm⁻² still exists in the interface between the sapphire substrate and GaN. In addition, since GaN is subjected to tensile strain while GaN is grown, cracks are formed on a surface of the substrate. Such phenomena immediately cause deterioration of electrostatic voltage resistance and reduction of internal quantum efficiency.

### SUMMARY OF THE INVENTION

The present invention is conceived to solve the aforementioned problems in the prior art. An object of the present invention is to provide a nitride-based light emitting device, wherein an interlayer is formed inside of an n-type nitride semiconductor layer, so that threading dislocation generated in the interface between a substrate and GaN is decreased, thereby improving electrostatic voltage resistance and the like.

According to the present invention for achieving the objects, there is provided a nitride-based light emitting device, which comprises a buffer layer, an n-type nitride semiconductor layer, an active layer and a p-type nitride semiconductor layer formed on a substrate, wherein an interlayer made of Al₁₋ₓSiₓN is formed inside of the n-type nitride semiconductor layer.

Si composition x of the interlayer is preferably ranged from 0.02 to 0.2, more preferably 0.02 to 0.12.

In addition, the interlayer has preferably a thickness of 10 to 500 nm and may be grown, for example, at 800 to 1000° C.

The interlayer may be formed at a position corresponding to ⅓ to ⅔ of a total thickness of the n-type nitride semiconductor layer. The interlayer and the n-type nitride semiconductor layer are formed in a superlattice structure in which an interlayer and an n-type nitride semiconductor layer are alternately laminated. In such a case, a thickness ratio of the interlayer to the n-type nitride semiconductor layer is preferably 1:10 to 3:7. The superlattice structure of the interlayer and the n-type nitride semiconductor layer is formed by alternately laminating the interlayer and the n-type nitride semiconductor layers 2 to 10 times.

### BRIEF DESCRIPTION OF THE DRAWINGS

FIG. 1 is a sectional view of a conventional nitride-based light emitting device;

FIG. 2 is a sectional view of a nitride-based light emitting device according to the present invention; and

FIG. 3 is a table showing electrostatic discharge (ESD) yields with respect to electrostatic voltage of the nitride-based light emitting device according to the present invention and the conventional nitride-based light emitting device.

### DETAILED DESCRIPTION OF THE INVENTION

Hereinafter, the present invention will be described in detail with reference to the accompanying drawings.

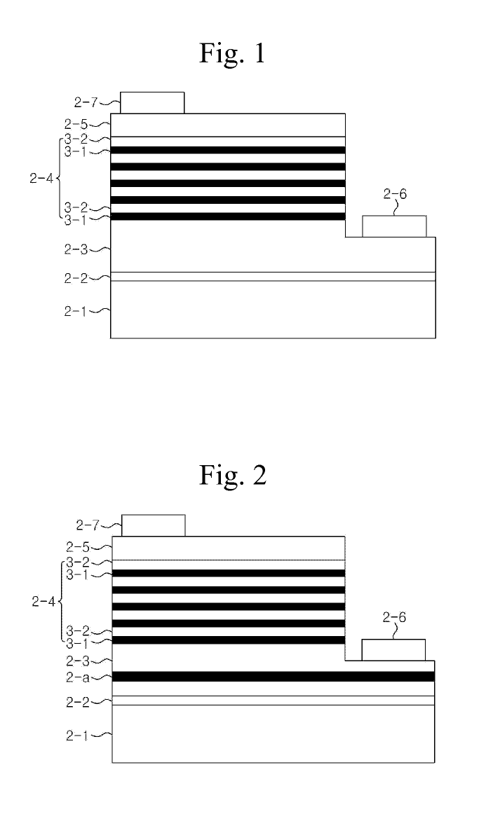

FIG. 1 is a sectional view of a conventional nitride-based light emitting device, and

FIG. 2 is a sectional view of a nitride-based light emitting device according to an embodiment of the present invention.

First of all, referring to FIG. 2, the nitride-based light emitting device comprises a buffer layer 2-2, an n-type nitride semiconductor layer 2-3, an active layer 2-4 and a p-type nitride semiconductor layer 2-5, which are sequentially formed on a substrate 2-1. An n-layer electrode 2-6 is formed on an exposed upper surface of the n-type nitride semiconductor layer 2-3, and a p-layer electrode 2-7 is formed on an exposed upper surface of the p-type nitride semiconductor layer 2-5.

An Al₁₋ₓSiₓN interlayer 2-a used in this embodiment is positioned inside of the n-type nitride semiconductor layer. In order to reduce threading dislocation generated in the interface between the substrate and GaN, the Al₁₋ₓSiₓN interlayer 2-a may be formed to have appropriate thickness and composition.

A first embodiment of the nitride-based light emitting device according to the present invention is as follows.

A variety of methods including a metal organic chemical vapor deposition (MOCVD) method, a molecular beam epitaxy (MBE) method, a hydride vapor phase epitaxy (HVPE) method and the like may be used as a growth method for a nitride-based light emitting device. In this embodiment, the MOCVD method is used.

Referring to FIG. 2, the buffer layer 2-2, the n-type nitride semiconductor layer 2-3, the Al₁₋ₓSiₓN interlayer 2-a positioned inside of the n-type nitride semiconductor layer, the active layer 2-4 and the p-type nitride semiconductor layer 2-5 are sequentially formed on the substrate 2-1.

The substrate 2-1, which is a wafer for fabricating a nitride-based light emitting device, is a heterogeneous substrate such as Al₂O₃, SiC, Si or GaAs, or a homogeneous substrate such as GaN. In this embodiment, a crystal growth substrate formed of sapphire is used.

The buffer layer 2-2 is used to reduce lattice mismatch between the substrate and the subsequent layers when crystals are grown on the substrate. The buffer layer 2-2 may be formed of InAlGaN series, SiC or ZnO. In this embodiment, a buffer layer formed of InAlGaN series is used.

The n-type nitride semiconductor layer 2-3 is a layer in which electrons are produced, and is formed of an n-type nitride-based semiconductor doped with Si. In this embodiment, as such an n-type nitride semiconductor layer, an n-type nitride semiconductor layer having an impurity concentration of 1×10¹⁷/cm³ to 5×10¹⁹/cm³ may be formed to a thickness of 1.0 to 5.0 μm using an inert gas such as SiH₄ or Si₂H₄, or an MO source such as DTBSi.

The interlayer 2-a positioned inside of the n-type nitride semiconductor layer is a layer for improving electrostatic voltage resistance, and is formed of Al₁₋ₓSiₓN. In this embodiment, the Al₁₋ₓSiₓN interlayer having an impurity concentration of 3×10¹⁸/cm³ to 5×10²⁰/cm³ may be formed to a thickness of 10 to 500 nm using an MO source of trimethylaluminum (TMAl) for obtaining Al and an inert gas such as SiH₄ or Si₂H₄ for obtaining Si, or an MO source such as DTBSi under NH₃ atmosphere at 800 to 1000° C.

The Al₁₋ₓSiₓN layer may be formed preferably at a composition of 0.02<x<0.2, and more preferably 0.02<x<0.12.

The Al₁₋ₓSiₓN interlayer may be formed at a position corresponding to ⅓ to ⅔ of the total thickness of the n-type nitride semiconductor layer.

The Al₁₋ₓSiₓN interlayer may be formed once inside of the n-type nitride semiconductor layer, and may be formed in a superlattice structure inside of the n-type nitride semiconductor layer.

In this case, the thickness ratio of the Al₁₋ₓSiₓN interlayer to the n-type nitride semiconductor layer may be 1:10 to 3:7.

Thereafter, the active layer 2-4 is formed on the n-type nitride semiconductor layer. The active layer 2-4 is preferably formed in a multiple quantum well structure in which InₓGa₁₋ₓN (0.1<x<1) quantum well layers 3-1 and In_{y}Ga_{1-y}N (0<y<0.5) quantum barrier layers 3-2 are alternately laminated at least 2 to 10 times. More preferably, each quantum well layer 3-1 is formed to a thickness of 1 to 4 nm and an In content of 0.1<x<0.4, and each quantum barrier layer 3-2 is formed to a thickness of 5 to 20 nm and an In content of 0<y<0.2.

Subsequently, the p-type nitride semiconductor layer 2-5 doped with Mg is formed on the active layer 2-4. Here, trimethylgallium (TMGa) or triethylgallium (TEGa) may be used as a source gas for Ga, and ammonia (NH₃) or dimethylhydrazine (DMHy) may be used as a source gas for N. CP₂Mg or DMZn may be used as a source gas for Mg. The p-type nitride semiconductor layer 2-5 having Mg of 3×10¹⁷/cm³ to 8×10¹⁷/cm³ is formed to a thickness of 1-3 μm using the source gas. Thereafter, mesa-etching is appropriately performed, and the n-layer electrode 2-6 and the p-layer electrode 2-7 are then formed on the exposed upper surfaces of the n-type nitride semiconductor layer 2-3 and the p-type nitride semiconductor layer 2-5, respectively.

### COMPARATIVE EXAMPLE

A nitride light emitting device is fabricated under the same condition as the aforementioned embodiment except that an Al₁₋ₓSiₓN interlayer employed in the present invention is omitted, which is illustrated in FIG. 1.

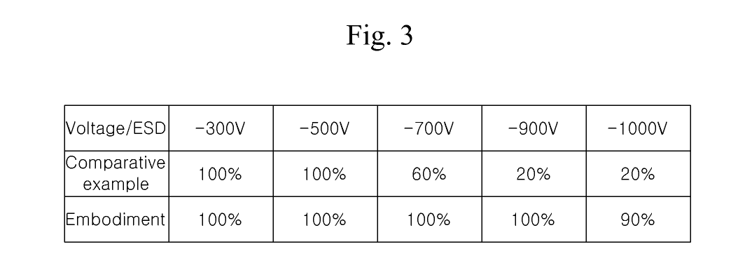

Table of FIG. 3 shows ESD results obtained by applying an electrostatic voltage from −100V to −1 kV stepwise to the nitride light emitting devices according to the aforementioned embodiment and the comparative example.

As shown in FIG. 3, when the electrostatic voltage is increased from −100V to −1 kV, it can be seen that the comparative example has an electrostatic voltage resistance of a level of −500V ESD. On the other hand, it can be seen that the embodiment using the Al₁₋ₓSiₓN interlayer has an electrostatic voltage resistance of a level of −900V ESD.

As such, an Al₁₋ₓSiₓN interlayer is formed inside of an n-type semiconductor layer, so that threading dislocation generated from the initial stage of the growth of the n-type nitride-based semiconductor layer due to lattice mismatch between the substrate and the n-type nitride-based semiconductor layer is reduced, and tensile strain generated while the n-type nitride-based semiconductor layer is grown is decreased, thereby improving electrostatic voltage resistance.

In the aforementioned embodiment, the nitride-based light emitting device has been described for illustrative purposes. However, it will be understood by those skilled in the art that the present invention can be usefully applied to other nitride-based optical devices having a similar structure such as semiconductor laser devices.

As described above, according to the present invention, an interlayer reduces threading dislocation generated from the initial stage of the growth of the n-type nitride-based semiconductor layer due to lattice mismatch between the substrate and the n-type nitride-based semiconductor layer, and decreases tensile strain generated while the n-type nitride-based semiconductor layer is grown, thereby improving electrostatic voltage resistance.

Although the present invention has been described in connection with preferred embodiments, the present invention is not limited to specific embodiments but is interpreted by the appended claims. Also, it will be understood by those skilled in the art that various modifications and changes can be made thereto without departing from the spirit and scope of the invention defined by the appended claims.

What is claimed is:

1. A nitride-based light emitting device, comprising a buffer layer, an n-type nitride semiconductor layer, an active layer and a p-type nitride semiconductor layer formed on a substrate,
wherein an interlayer made of Al₁₋ₓSiₓN is formed inside of the n-type nitride semiconductor layer.

2. The nitride-based light emitting device as claimed in claim 1, wherein x is in the range of 0.02 to 0.2.

3. The nitride-based light emitting device as claimed in claim 2, wherein x is in the range of 0.02 to 0.12.

4. The nitride-based light emitting device as claimed in claim 1, wherein the interlayer has a thickness of 10 to 500 nm.

5. The nitride-based light emitting device as claimed in claim 1, wherein the interlayer is grown at 800 to 1000° C.

6. The nitride-based light emitting device as claimed in claim 1, wherein the interlayer is formed at a position corresponding to ⅓ to ⅔ of a total thickness of the n-type nitride semiconductor layer.

7. The nitride-based light emitting device as claimed in claim 1, wherein the interlayer and the n-type nitride semiconductor layer are formed in a superlattice structure in which an interlayer and an n-type nitride semiconductor layer are alternately laminated.

8. The nitride-based light emitting device as claimed in claim 7, wherein a thickness ratio of the interlayer to the n-type nitride semiconductor layer is 1:10 to 3:7.

9. The nitride-based light emitting device as claimed in claim 7, wherein the superlattice structure of the interlayer and the n-type nitride semiconductor layer is formed by alternately laminating the interlayer and the n-type nitride semiconductor layers 2 to 10 times.
